(19) United States
(12) Patent Application Publication
(10) Pub. No.: US 2017/0201067 A1
(43) Pub. Date: Jul. 13, 2017

(54) METHOD FOR IMPROVEMENT OF THE BEAM QUALITY OF THE LASER LIGHT GENERATED BY SYSTEMS OF COHERENTLY COUPLED SEMICONDUCTOR DIODE LIGHT SOURCES

(71) Applicants: Vitaly Shchukin, Berlin (DE); Nikolay Ledentsov, Berlin (DE)

(72) Inventors: Vitaly Shchukin, Berlin (DE); Nikolay Ledentsov, Berlin (DE)

(21) Appl. No.: 14/104,259

(22) Filed: Dec. 12, 2013

Related U.S. Application Data
(60) Provisional application No. 61/748,150, filed on Jan. 2, 2013.
(60) Provisional application No. 61/802,772, filed on Mar. 18, 2013.

(51) Int. Cl. H01S 5/065; H01S 5/22; H01S 5/022; H01S 5/40; H01S 5/14

(52) U.S. Cl. CPC H01S 5/0655; H01S 5/4025; H01S 5/141; H01S 5/02288; H01S 5/22

(57) ABSTRACT

A semiconductor optoelectronic system contains a primary semiconductor optoelectronic system, a first wavefront, a set of diffracting elements, and a second wavefront. The primary semiconductor electronic system is a single laser of a set of gain chips, bars, or stacks coherently coupled in an external resonator, the system is capable to generate a single vertical mode single lateral mode laser light. The near field on the first wavefront in the immediate vicinity of the system contains illuminated spots and dark spots, the latter dominate. The set of diffracting element transforms the near field of the laser light, and, hence, also the far field pattern, providing a significantly smaller beam divergence and, respectively, a higher brightness.

### REFERENCE TO RELATED APPLICATIONS

This application claims an invention which was disclosed in Provisional Application No. 61/748,150, filed Jan. 2, 2013, entitled “METHOD FOR IMPROVEMENT OF THE BEAM QUALITY OF THE LASER LIGHT GENERATED BY SYSTEMS OF COHERENTLY COUPLED SEMICONDUCTOR DIODE LASERS” and an invention which was disclosed in Provisional Application No. 61/802,772, filed Mar. 18, 2013, entitled “METHOD FOR IMPROVEMENT OF THE BEAM QUALITY OF THE LASER LIGHT GENERATED BY SYSTEMS OF COHERENTLY COUPLED SEMICONDUCTOR DIODE LASERS”. The benefit under 35 USC §119(e) of the United States provisional application is hereby claimed, and the aforementioned applications are hereby incorporated herein by reference.

### BACKGROUND OF THE INVENTION

Field of the Invention

The invention pertains to the field of semiconductor optoelectronic devices. More particularly, the invention pertains to high-power high-brightness semiconductor diode lasers and optical systems based thereupon.

Description of Related Art

There is a need in high-performance semiconductor diode lasers for numerous applications including, but not limited to illumination, sensing, frequency conversion, projection displays material processing. For these applications high power and high brightness (power emitted in a unit solid angle) are of key importance.

Conventional prior art edge emitting laser have severe limitations. First, the output power is limited by the catastrophic optical mirror damage, and all technological improvements including facet passivation, zinc diffusion, or proton bombardment still have limitations in optical power density. To achieve higher power by keeping the same power density one needs using broad area lasers. However, the lasing from broad area lasers is typically multimode and also suffers from beam filamentation which renders the laser radiation not focusable.

Using semiconductor diode laser as pump source for pumping a solid state laser or a fiber laser is possible but expensive and also consumes additional power. Therefore there is a need in the art in optical systems based solely on semiconductor diode lasers, whereas such optical systems allow high power high brightness laser emission.

Earlier approaches have been proposed, first, on semiconductor diode lasers or semiconductor diode gain chips having a thick vertical waveguide providing a narrow vertical far field, and second, on selection of the lateral optical modes thus providing a narrow lateral far field. The first goal can be achieved, e.g., by a passive cavity laser disclosed in the U.S. Pat. No. 8,472,496, filed Jul. 6, 2010, entitled “OPTOELECTRONIC DEVICE AND METHOD OF MAKING SAME”, issued Jun. 25, 2013, by one inventor of the inventors of the present invention, and in the U.S. Pat. No. 8,576,472, filed Oct. 28, 2010, entitled “OPTOELECTRONIC DEVICE WITH CONTROLLED TEMPERATURE DEPENDENCE OF THE EMISSION WAVELENGTH AND METHOD OF MAKING SAME”, issued Nov. 5, 2013, by one inventor of the inventors of the present invention, whereas these both patents are incorporated herein by reference in their entirety. An alternative realization of a semiconductor diode laser with a thick vertical waveguide is Tilted Wave Laser proposed in the U.S. Pat. No. 7,421,001, filed Jun. 16, 2006, entitled “EXTERNAL CAVITY OPTOELECTRONIC DEVICE”, issued Sep. 2, 2008, and in the U.S. Pat. No. 7,583,712, filed Jan. 3, 2007, entitled “OPTOELECTRONIC DEVICE AND METHOD OF MAKING SAME”, issued Sep. 1, 2009, both by the inventors of the present invention, whereas these both patents are incorporated herein by reference in their entirety. One more alternative approach is related to a laser based on a vertical photonic band crystal, disclosed in the US patent “SEMICONDUCTOR LASER BASED ON THE EFFECT OF PHOTONIC BAND GAP CRYSTAL-MEDIATED FILTRATION OF HIGHER MODES OF LASER RADIATION AND METHOD OF MAKING THE SAME”, U.S. Pat. No. 6,804,280, filed Sep. 4, 2001, issued Oct. 12, 2004, by the inventors of the present invention, whereas this patent is incorporated herein by reference in its entirety. An effective selection of the lateral modes can be achieved by a multistripe chip, wherein the multistripes are formed on top of a semiconductor laser diode having a thick vertical waveguide and/or by using a systems of coherently coupled bars or stacks, wherein each diode gain chip has a thick vertical waveguide and a broad lateral waveguide, and the selection of the modes is provided by an external resonator. These two approaches were disclosed in the U.S. Pat. No. 7,949,031, entitled “OPTOELECTRONIC SYSTEMS PROVIDING HIGH-POWER HIGH-BRIGHTNESS LASER LIGHT BASED ON FIELD COUPLED ARRAYS, BARS, AND STACKS OF SEMICONDUCTOR DIODE LASERS”, filed Aug. 28, 2008, issued May 24, 2011, by the inventors of the present invention, whereas this patent is incorporated herein by reference in its entirety.

However, such solution that may provide a high power lasing in a single optical mode can still be insufficient. FIG. 1 shows schematically a prior art semiconductor diode laser 100 having a thick vertical waveguide and a multistripe structure 110 on top, wherein the multistripes 110 form a lateral photonic band crystal capable to provide lasing in a single lateral optical mode. The laser 110 has a front facet 160 through which the laser light comes out of the device. A typical case is illustrated in FIG. 1, wherein the distance between stripes is much larger than the width of the stripes, and the spots 120 illuminated by the laser light, i.e. the spots on which the optical field in the lasing optical mode has a significant intensity are separated by much larger non-illuminated areas, on which the intensity of the optical field is considerably small.

A one skilled in the art will appreciate that the main features of the near filed pattern and the far field pattern can be addressed by a simple one-dimensional model of the effective refractive index varying in the direction perpendicular to the stripes. FIG. 2A shows the lateral profile of the effective refractive index profile of a 9-stripe structures, having the refractive index step of Δn=0.005, the width of the stripes 5 μm, and the distance between the stripes 25 μm. The electric field strength profile indicates illuminated areas beneath the stripes and “dark” areas in between. Calculations are performed for the wavelength of the light 1 μm. FIG. 2B depicts the far field pattern revealing optical power distributed over nine narrow lobes. The dashed curve depicts a Gaussian envelope having 8.8 degrees full width at half maximum. Even if the multistripe laser is capable to provide single mode lasing, the beam quality providing of the device is poor and to focus the emitted laser light into an optical fiber or onto a small spot on the target surface of a material to be processed remains challenging.

Thus, there exists a strong need in the art for broad area filament-free, lasers and laser systems providing high power high brightness lasing. Solving the above problem is possible with the present invention.

### SUMMARY OF THE INVENTION

The present invention discloses a semiconductor optoelectronic system improving beam quality of a single mode laser radiation. A semiconductor optoelectronic system generates coherent laser light in a single vertical mode and single lateral mode. Such system can be realized as a semiconductor diode laser chip having a multistripe on top, wherein this multistripe forms a lateral periodicity or selective losses allowing mode selection. As an alternative, such system can be realized as a coherently coupled bar or stack of semiconductor diode gain chips. Placing them in an external resonator can also provide lasing in a single mode. In yet another approach different multiple gain sections may be used to amplify the emission of a single single mode laser which is split to multiple amplification channels. The key feature of these systems is that the coherent laser light comes out of the system through a number of spots. The system can also be regarded as a set of multiple sources of light coupled coherently. Each of the sources has a small aperture, and the distance between the sources is larger than the size of the apertures. A strong disadvantage of such device configuration is a large beam divergence of the emitted laser light and, hence, reduced brightness.

The present invention discloses an approach allowing increase of the brightness of a coherent laser array or an array of coherent diffraction spots. A set of diffracting elements, e.g. of collimating lenses or collimating mirrors are placed at some distance and direction with respect to the apertures or diffraction spots. The distance between the aperture and, say, a collimating lens is preferably close to the focal length of the lens at a given angle. The lenses are larger than the aperture or the diffracting spot size. In the preferred embodiments, the lenses cover nearly the entire distance between the neighboring apertures. The emitted light remains coherent, but the beam divergence strongly reduces, and the brightness increases.

If the semiconductor system is a semiconductor laser chip with a multistripe on top, the collimating lenses are preferably configured in a row opposite to the stripes. If the semiconductor system is a stack of the diode gain chips coherently coupled in an external resonator by means of an external semi-transparent mirror, the collimating lenses are preferably placed in a vertical column at the outer side of the external mirror, or form a two-dimensional pattern in both vertical and lateral directions at the outer side of the external mirror.

### BRIEF DESCRIPTION OF THE DRAWINGS

FIG. 1. Schematic view of a prior art diode laser with a multistripe structure on top forming a lateral photonic band crystal.

FIG. 2A. Schematic view of the lateral profile of the effective refractive index and the near field profile for the device of FIG. 1.

FIG. 2B. Far field profile of the device of FIG. 1.

FIG. 3A. An optoelectronic system according to one embodiment of the present invention, wherein a set of lenses are placed in front of the front facet of the multistripe laser, the size of the lenses being close to the distance between the stripes. The resulting far field is generated through near field coupling of the apertures to the diffracting lenses.

FIG. 3B. An optoelectronic system according to another embodiment of the present invention, wherein a set of lenses are placed away from the front facet of the multistripe laser, the size of the lenses being much larger that the distance between the stripes. The resulting far field results from the diffraction of the multilobe far field emission of the array in FIG. 2B.

FIG. 4A. Schematic view of the lateral profile of the effective refractive index on the second wavefront behind the lenses showing broader areas of a higher refractive index and narrower areas of a lower refractive index, and the near field profile at the second wavefront.

FIG. 4B. Far field profile of the optoelectronic system of FIG. 3 revealing an improved beam quality with respect to that of FIG. 2B.

FIG. 5A. Refractive index profile in the vertical direction in a passive cavity edge-emitting laser.

FIGS. 5B through 5D. Vertical profiles of the electric field strengths for the highest-order localized optical modes in the passive cavity laser of FIG. 5A.

FIG. 5B. The localized optical mode of the highest order N.

FIG. 5C. The localized optical mode of the order (N−1).

FIG. 5D. The localized optical mode of the order (N−2).

FIG. 6. Vertical far field profile of the optical mode of FIG. 5B of the passive cavity laser.

FIG. 7. An optoelectronic system according at another embodiment of the present invention, wherein two narrow tilted vertical beams generated by a passive cavity laser or a tilted wave laser are declined by prisms and, after passing two lenses, form a fundamental vertical optical mode on the wavefront behind the lenses.

FIG. 8. An optoelectronic system according at another embodiment of the present invention, wherein two narrow tilted vertical beams generated by a passive cavity laser or a tilted wave laser are declined and collimated by collimating mirrors, after passing two lenses, form a fundamental vertical optical mode on the wavefront behind the lenses.

FIG. 9A. An optical system comprising a passive cavity laser or a tilted wave laser and a lens, which converts two narrow tilted lobes emitted from the laser to two parallel beams.

FIG. 9B. Diffraction profile containing a predominant single narrow beam, whereas the diffraction profile is created of two parallel beams forming by the system of FIG. 9A.

FIG. 10A. A prior art optoelectronic system formed by a stack of tilted wave lasers coherently coupled via an external mirror.

FIG. 10B. An optoelectronic system according to yet another embodiment of the present invention, wherein a set of lenses arranged vertically, is placed behind the external mirror of FIG. 7A, to reduce substantially the beam divergence.

FIG. 11A. Far-field lateral pattern of the light emitted by a multistripe chip, according to an embodiment of the present invention. Lateral fundamental (in-phase) mode.

FIG. 11B. Far-field lateral pattern of the light emitted by a multistripe chip, according to an embodiment of the present invention. Lateral oscillating (out-of-phase) mode.

FIG. 11C. A system with a lens having a variable focal length, according to an embodiment of the present invention.

FIG. 12. A system for generating wavelength-stabilized light with multiple wavelengths, according to an embodiment of the present invention.

FIGS. 13A through 13D. Principles of a system with a built-in lens, according to an embodiment of the present invention.

FIG. 13A. Lateral profile of the effective refractive index and near field of the out-of-phase (oscillating) lateral optical mode for a conventional multistripe chip.

FIG. 13B. Far field of the out-of-phase mode of FIG. 13A showing strong satellites.

FIG. 13C. Lateral profile of the effective refractive index and near field profile of the out-of-phase (oscillating) lateral optical mode for a multistrip chip containing a built-in lens, according to an embodiment of the present invention.

FIG. 13D. Far field of the out-of-phase mode of FIG. 13C showing suppressed satellites.

FIGS. 14A through 14H. Principles of a system with a built-in lens, according to an embodiment of the present invention.

FIG. 14A shows schematically a multi-stripe array.

FIG. 14B. Injection current profile of the multistripe array of FIG. 14A showing that only one stripe is pumped by electric current.

FIG. 14C. Near field profile of the fundamental lateral optical mode of the multi-stripe array of FIG. 14A, whereas the mode is formed by the current-guiding with the injection current profile of FIG. 14B. Electric field strength is plotted.

FIG. 14D. Near field profile of the same fundamental lateral optical mode, as in FIG. 14C, but the intensity plot shows a narrower maximum. Thus the mode intensity is concentrated to a great extent at a single stripe.

FIG. 14E shows schematically the same multi-stripe array as FIG. 14F.

FIG. 14F shows an injection current profile whereas a few neighboring stripes are pumped in a specific way.

FIG. 14G. Near field profile of the fundamental lateral optical mode of the multi-stripe array of

FIG. 14E, whereas the mode is formed by the current-guiding with the injection current profile of FIG. 14F. Electric field strength is plotted.

FIG. 14H. Near field profile of the same fundamental lateral optical mode, as in FIG. 14G, but the intensity is plotted.

FIG. 15A shows the far field profiles of the fundamental lateral optical mode of FIGS. 14C (or 14D).

FIG. 15B depicts the far field profiles of the fundamental lateral optical mode of FIGS. 14G (or 14H) showing the significant narrowing of the far field due to the specific pumping of a few neighboring stripes as in FIG. 14F.

FIG. 16. A schematic view of an optoelectronic system according to another embodiment of the present invention, wherein an external mirror provides single mode operation.

FIG. 17. A schematic view of an optoelectronic system according to an embodiment of the present invention, wherein a holographic Brag grating provides single mode operation.

FIG. 18. A schematic view of an intracavity system for frequency conversion according to another embodiment of the present invention.

FIG. 19. A schematic view of an intracavity system for frequency conversion according to yet another embodiment of the present invention.

FIG. 20. A schematic view of an intracavity system for frequency conversion according to a further embodiment of the present invention.

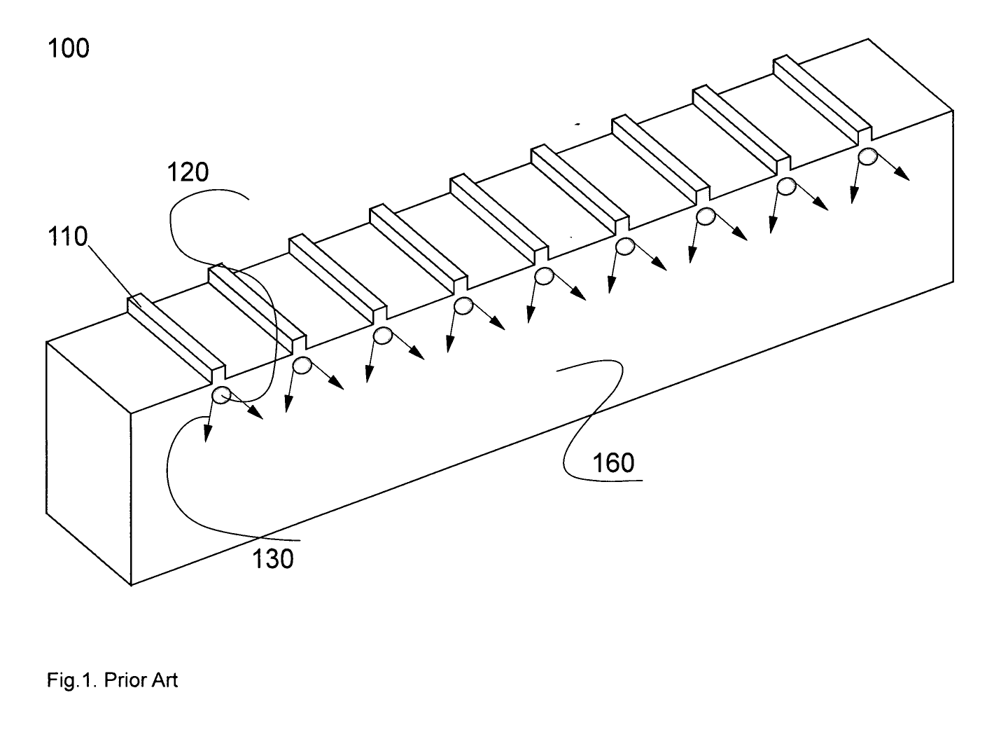

### DETAILED DESCRIPTION OF THE INVENTION

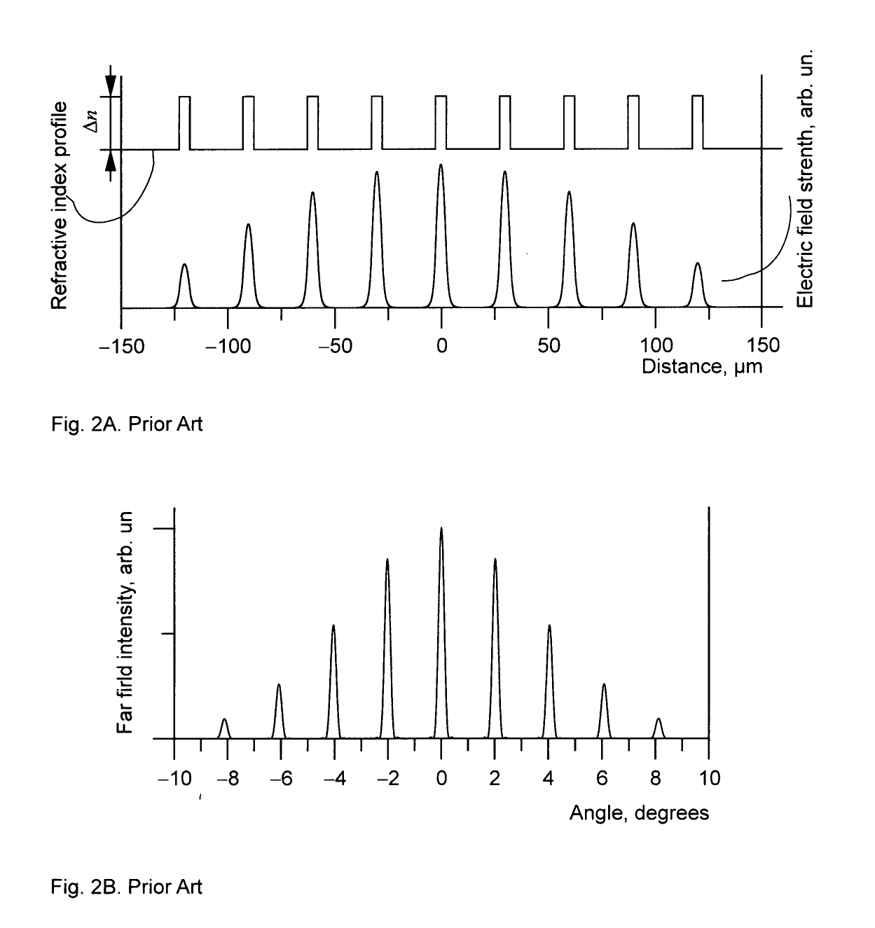

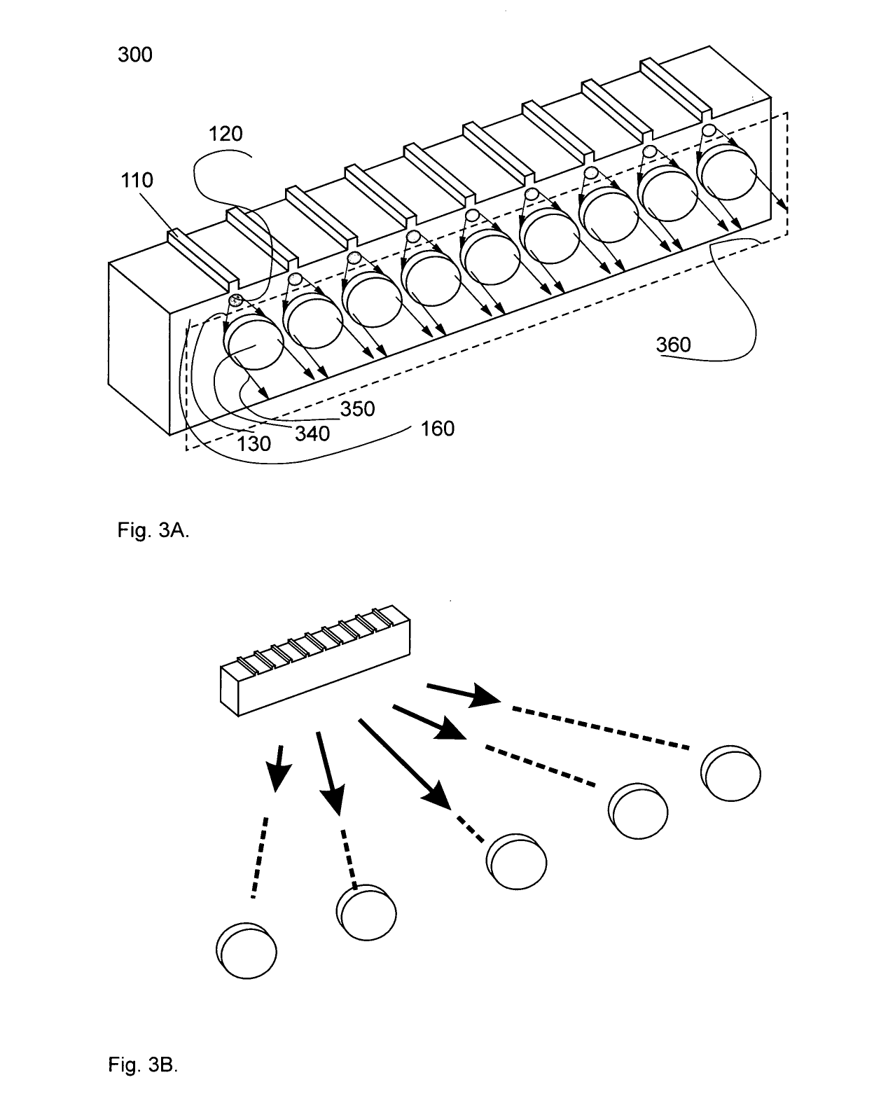

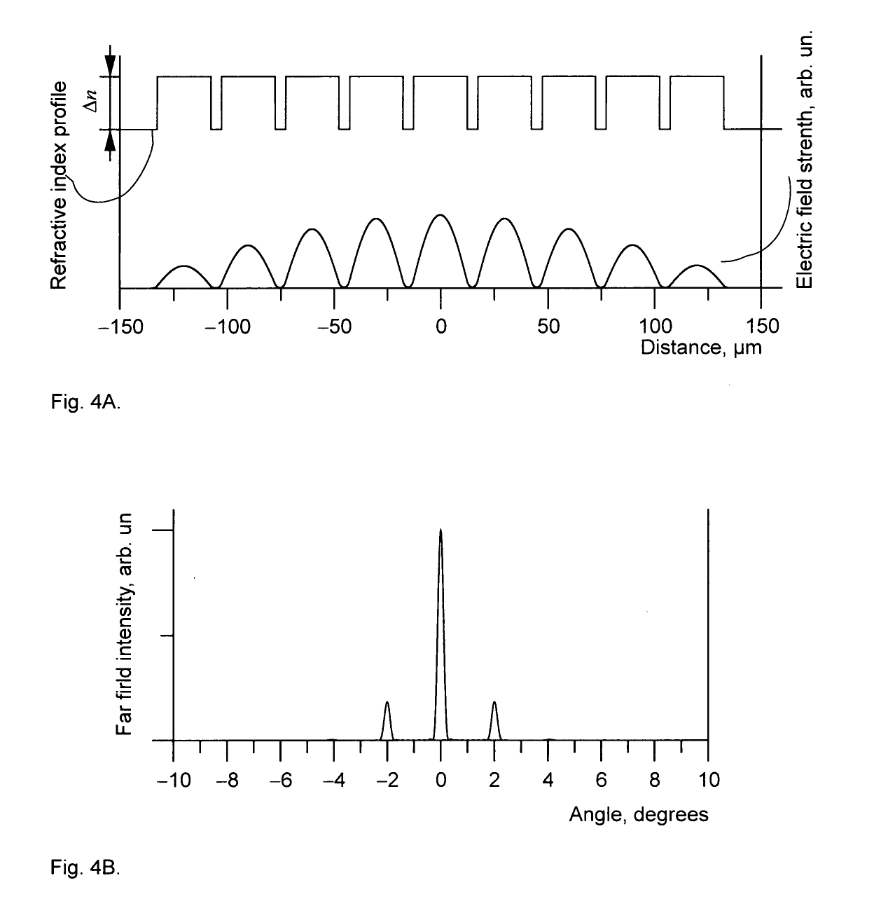

FIG. 3A shows schematically an optoelectronic system 300 according to an embodiment of the present invention. A set of lenses 340 is placed in front of the facets 160. The size of the lenses is preferably close to the separation between the stripes, such that the major part of a line in the lateral direction on the front facet of the laser is covered by the lenses. The optical beam 350 of the laser light behind the lenses 340 differs drastically of that of FIG. 2A. In FIG. 3B another embodiment is shown. In this case the lenses are placed away from the facets and the initial far field is formed by the diffracting facet apertures of the laser array. The lenses are placed at positions where the far field is already formed and they introduce a next plane of the diffracting units at adjustable angles to redirect and reshape the far field by a new diffraction pattern. The sizes of the lenses in this case should be preferably larger than the total facet size of the laser bar. FIG. 4A models schematically the effective lateral profile of the refractive index in the lateral direction in the immediate vicinity behind the lenses. The lenses through which the light is coming are modeled by the areas of a higher effective refractive index, and the narrow spacers between the lenses through which the light does not come are modeled by narrow areas having a lower refractive index. FIG. 4A shows the narrow field profile on the second wavefront 360, revealing a significantly stronger coupling of the light between the areas behind neighboring lenses. On this figure the areas behind lenses are 25 μm wide, and the spacer being 5 μm wide. FIG. 4B shows the far field profile on which most of the side angular lobes are suppressed. The Gaussian envelope has now 2.8 degrees full width at half maximum, implying reduction by more than 3 times with respect to the pattern in FIG. 3C.

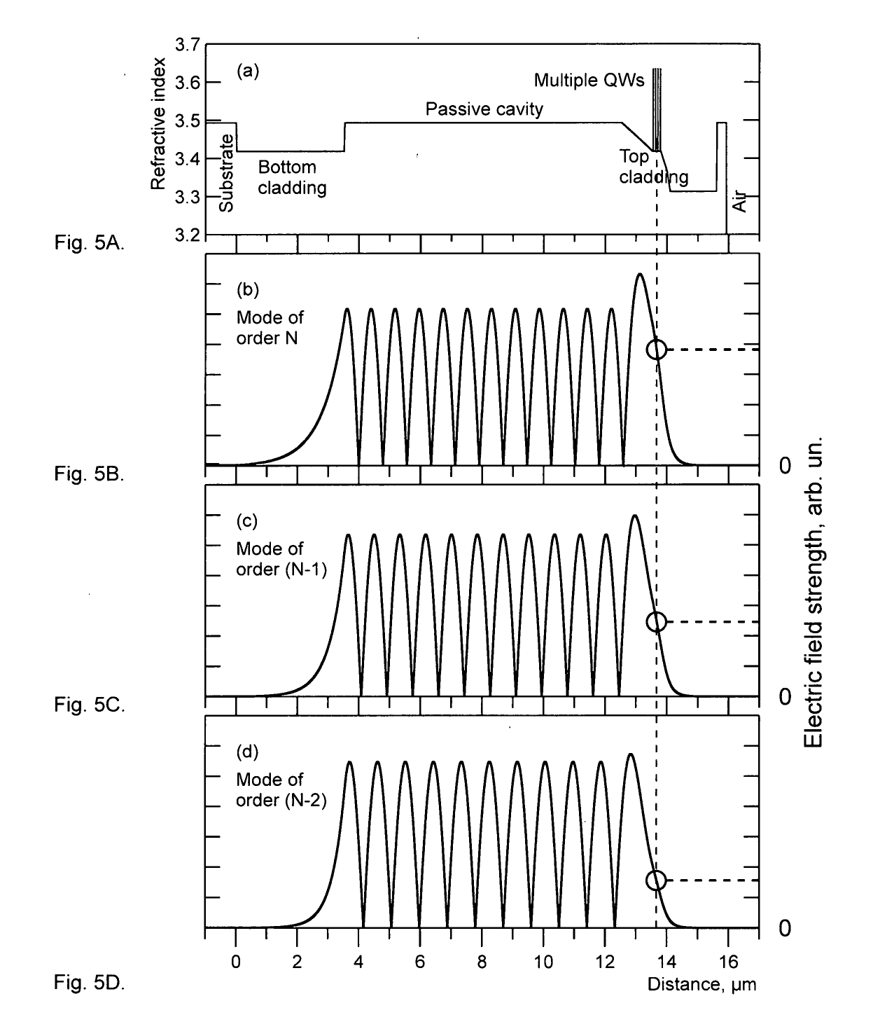

FIGS. 5A through 5D explains in detail the operation of an semiconductor edge-emitting passive cavity laser or a corresponding semiconductor edge-emitting passive cavity gain chip as disclosed in in the U.S. Pat. No. 8,472,496, filed Jul. 6, 2010, entitled “OPTOELECTRONIC DEVICE AND METHOD OF MAKING SAME”, issued Jun. 25, 2013, by one inventor of the inventors of the present invention, and in the U.S. Pat. No. 8,576,472, filed Oct. 28, 2010, entitled “OPTOELECTRONIC DEVICE WITH CONTROLLED TEMPERATURE DEPENDENCE OF THE EMISSION WAVELENGTH AND METHOD OF MAKING SAME”, issued Nov. 5, 2013, by one inventor of the inventors of the present invention. The principle of mode selection is based on an exponential decrease of the optical modes in the cladding layers. FIG. 5A shows a vertical profile of the refractive index of a passive cavity laser. The active region based on a multiple quantum wells is placed within a top cladding. The structure confines N vertical optical modes, the higher modes with a lower effective refractive index are delocalized and extended over the entire substrate. The higher is order of the localized mode, the slower is its decay in the cladding layer. FIG. 5B shows the electric field strength profile of the localized mode of the highest order N. FIGS. 5C and 5D display the electric field strength profiles of the modes of the order (N−1) and (N−2), respectively. The electric field strength in each of the depicted modes in the active region is marked by a circle. One has to bear in mind, that FIGS. 5B through 5D display electric field strength, and that the discrimination in the field intensity in the active regions, and, hence, in the optical confinement factors will be stronger, approximately by a factor of 2 between the modes of the order N and (N−1).

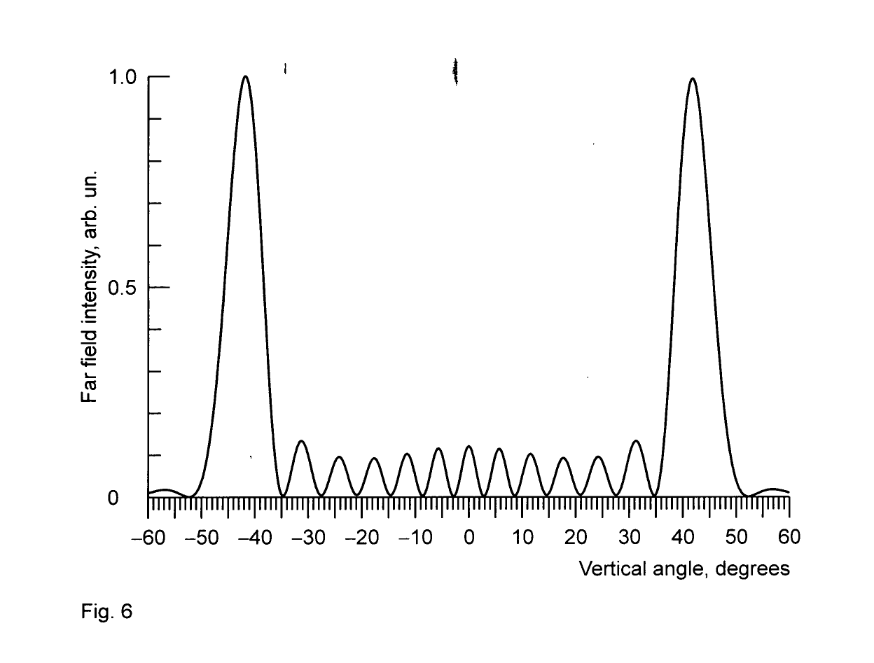

FIG. 6 shows the vertical far field of the mode of the order N of the edge-emitting passive cavity laser. The far field profile reveals two tilted narrow lobes (having 7.2 degrees full width at half maximum) and a moderately weak profile in the intermediate range of angles. One should bear in mind that, despite some similarity in the vertical far fields of the passive cavity laser and the tilted wave laser, there is a principal difference between these two types of device. The active region in a tilted wave laser is placed not in a cladding layer, but in a cavity resulting in a strong enhancement of the optical mode in the active region. Correspondingly, the dominant intensity of the far field is concentrated in the broad interval of intermediate angles between two narrow lobes and complex processing including trenches across the waveguide is necessary to suppress this undesired lasing in the broad angular interval (V. Shchukin et al., “Tilted Wave Laser”, IEEE Journal of Quantum Electronics, volume 47, issue 7, pages 1014-1027 (2011)). On the other hand, no strong enhancement of the optical mode in the active region occurs in the passive cavity lasers, and only a small part of the laser light is emitted in the broad angular interval, and no trenches are needed. The advantage of the passive cavity laser occurs at the expense of a reduction of the optical confinement factor.

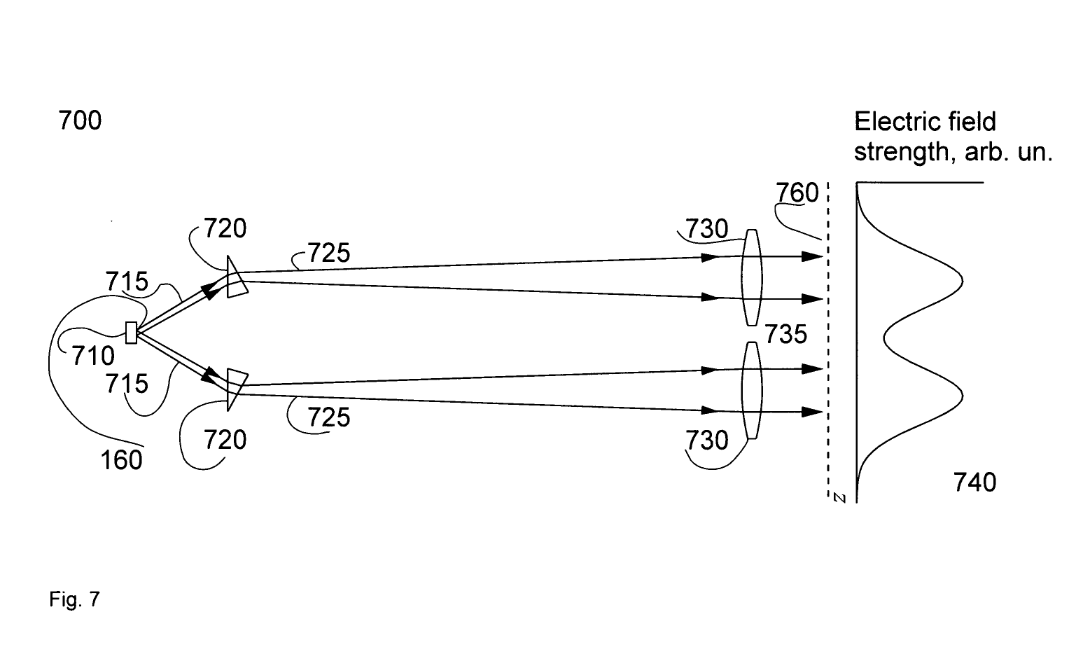

FIG. 7 shows schematically an optoelectronic system 700 according to another embodiment of the present invention. A passive cavity laser 710 emits laser light in two narrow tilted vertical lobes 715. Laser light comes through refracting prisms 720 form narrow beams 725 which come through the set of lenses 730. The set of lenses have two lenses in the vertical direction. It may have one or multiple lenses in the lateral direction. The divergence of the beam 735 behind the lenses nearly vanishes. Profile 740 depicts schematically the near field profile immediately behind the lenses. The near field profile has no nodes and corresponds effectively to the vertical fundamental mode of the system.

In yet another embodiment of the present invention, a tilted wave laser is used in a system, similar to that of FIG. 7, to emit light in two vertical lobes.

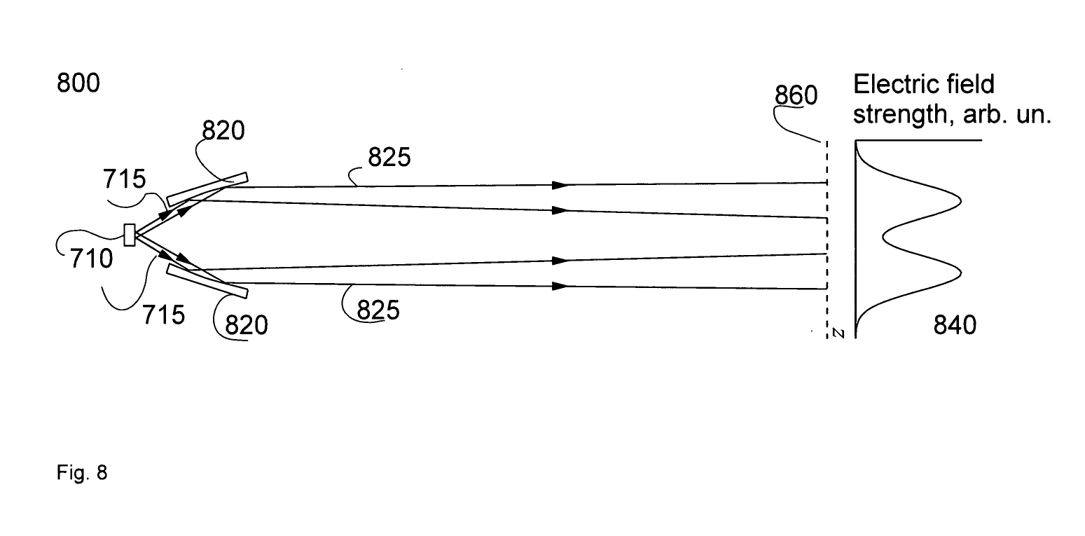

FIG. 8 shows schematically an optoelectronic system 800 according to a further embodiment of the present invention. A passive cavity wave laser 710 emits laser light in two narrow tilted vertical lobes 715. Laser light is reflected by the collimating mirrors 820 to form two beams 825 having a very low beam divergence. At the wavefront 860 sufficiently far from the source of the light, the near field pattern looks like the curve 840, which corresponds to the vertical fundamental mode of the system.

In another embodiment of the present invention, a tilted wave laser is used in a system, similar to that of FIG. 8, to emit light in two vertical lobes.

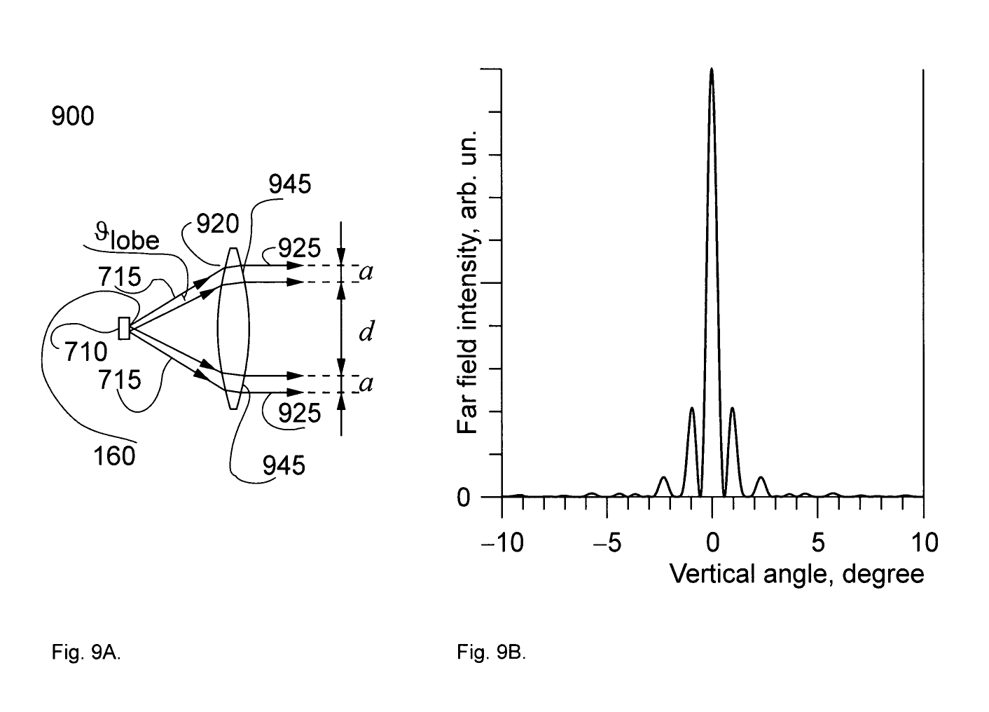

FIG. 9A shows schematically an optoelectronic system 900 according to yet another embodiment of the present invention. A passive cavity laser 710 emits laser light in two narrow vertical lobes 715. Laser light impinges on a single lens 920 that converts each of the narrow vertical lobes into two nearly parallel beams 925. It is preferred that the beams 925 formed by the lens 920 are directed parallel to the lateral plane or at an angle which does not exceeds 0.5 degrees with respect to the lateral plane and have the full width at half maximum which does not exceed 0.5 degrees. The two spots 945 act as two coherent to each other effective sources of light that undergoes further diffraction that can be considered as the diffraction of light from two slits. Depending on particular size a of the spots and the distance d between the spots, the far field of the diffracted light can be single-lobe.

FIG. 9B shows an example of an approximately single-lobe far field of the light diffracted at a lens, calculated for a=35 μm, d=50 μm and the wavelength o light 1 μm.

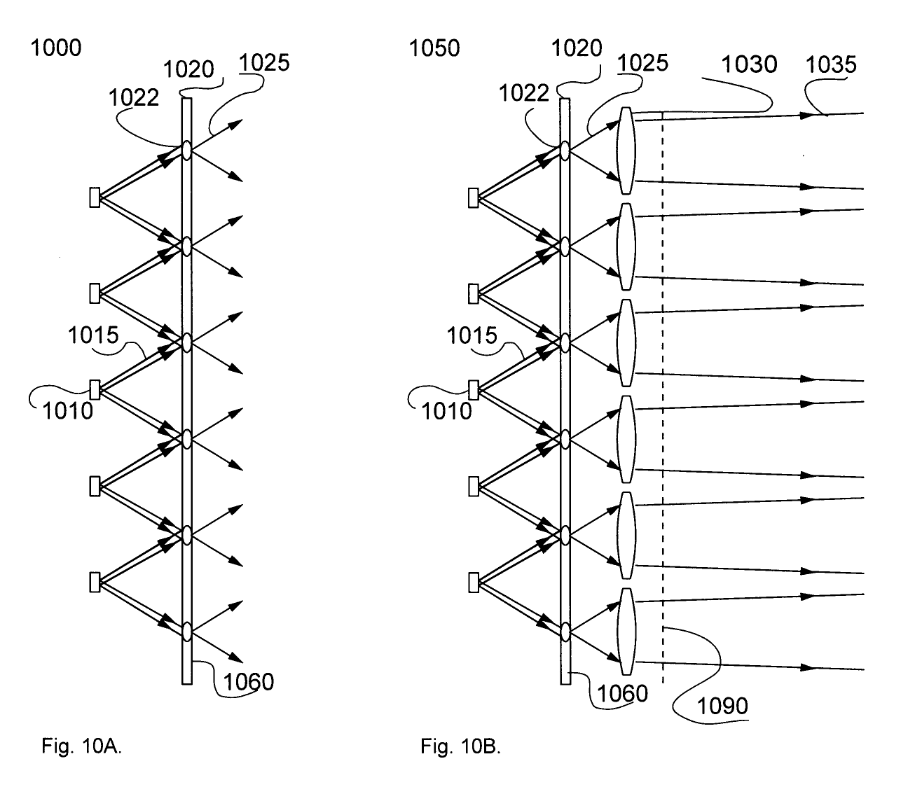

FIG. 10A shows a prior a prior art semiconductor optoelectronic system 1000 including a stack of tilted wave lasers 1010 coherently coupled via an external mirror 1020. Narrow vertical beams 1015 emitting by the passive cavity lasers 1010 are coupled, once emitted by the neighboring devices, forming illuminated spots 1022. The light 1025 further propagates behind the spots leading to a rather complex far field pattern resembling that of FIG. 2B and having a poor beam quality.

FIG. 10B shows schematically an optoelectronic system 1050 according to yet another embodiment of the present invention. A set of lenses 1030 in the vertical direction is placed behind the external mirror 1020. Diffracted beams 1035 reveal a significantly smaller beam divergence thus improving the brightness of the system.

In another embodiment of the present invention, tilted wave lasers are used as light sources in an optical system similar to that of FIG. 10.

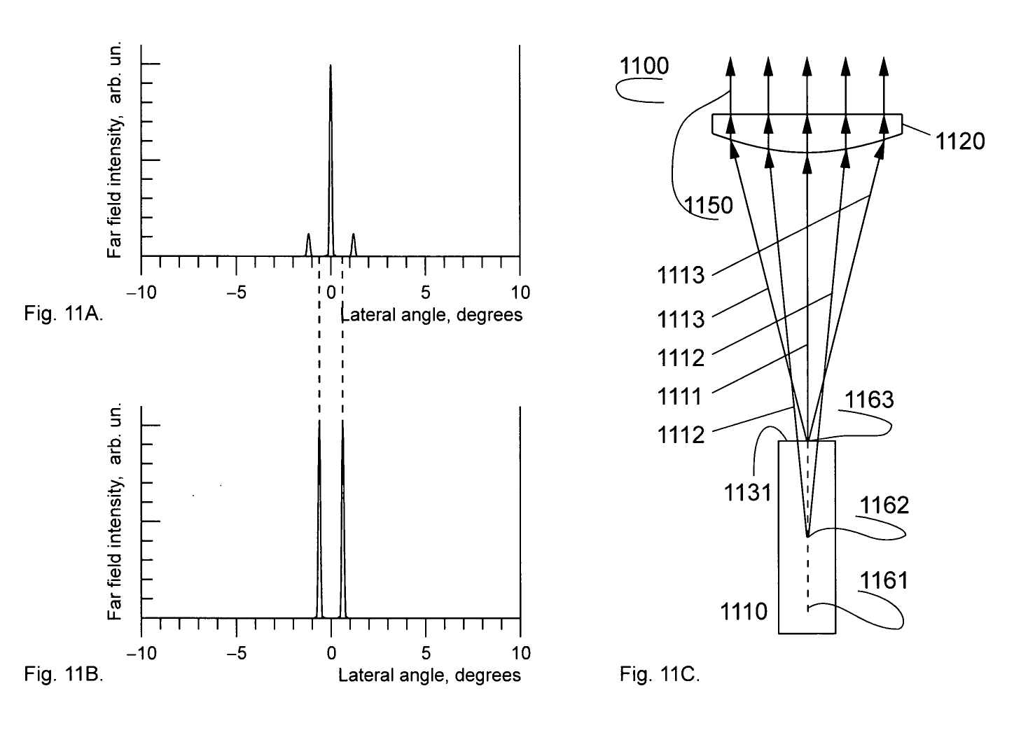

FIGS. 11A through 11C refer to an optoelectronic system according to a further embodiment of the present invention, wherein an improvement of the optical beam is provided by a lens having a variable focal length. The system is based on a semiconductor laser with multistripes. A one skilled in the art will appreciate that a multistripe chip has a plurality of the lateral optical modes, out of which two modes have preferred conditions for lasing. These are the lateral fundamental mode (or in-phase mode) and the lateral oscillating mode (or out-of-phase) mode. FIG. 11A shows the lateral far field of the lateral in-phase mode revealing one major peak at the zero lateral angle and two satellite peaks. Further satellite peaks can have a very small intensity. FIG. 11B shows the lateral far field of the lateral out-of-phase mode revealing two peaks. Dashed lines connecting FIG. 11A and FIG. 11B show that the two modes have peaks at different lateral angles. Therefore, if one considers a position far enough from the chip, at a certain angle, most of the light coming to this point will be light of a single lateral optical mode. This allows using a set of lenses, like in FIG. 3B, wherein each lens is optimized for a corresponding lateral optical mode. FIG. 11C refers to an alternative embodiment of an optoelectronic system (1100) using a single lens with a variable focal length. Semiconductor multistripe laser 1110 emits light in multiple lateral modes. Three lateral modes are shown schematically as rays directed at different angles, These are: the mode 1111 directed perpendicular to a laser facet 1131, the mode 1112 directed symmetrically in 2 directions in the lateral plane, and the mode 1113 directed in 2 directions in the lateral plane at a larger angle. These three modes have foci at different positions. The mode 1113 having a larger lateral angle has its focus 1163 at the front facet 1131 of the laser 1110. The mode 1112 having a smaller lateral angle, has its focus 1162 deep of the laser chip. The mode 1111 having the minimum lateral angle ahs its focus 1161 deep in the laser chip even at a larger distance from the front facet 1131. The light in all modes impinges on a lens 1120. The lens 1120 is a lens with a variable focal length, L=L(x), wherein the focal length L is a function of the lateral coordinate x. The function is selected such that the light behind the lens 1150 forms preferably a parallel beam or a beam close to parallel.

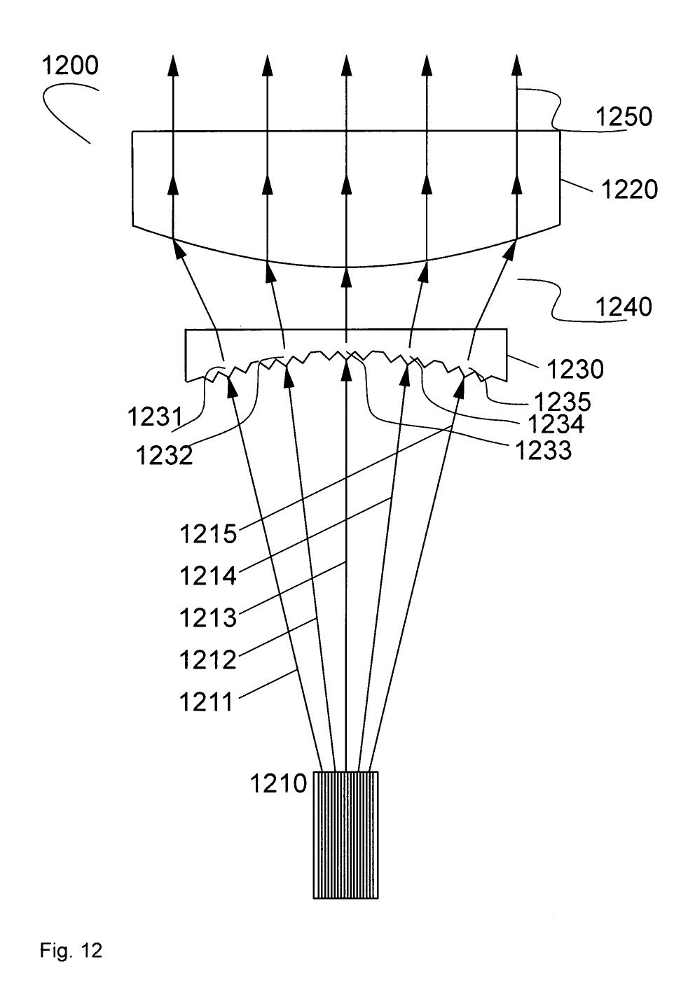

FIG. 12 shows an optoelectronic system 1200, according to an embodiment of the present invention. A semiconductor gain chip 1210 having multiple stripes on the top surface emits light in a plurality of lateral optical modes, directed at different lateral angles and shown schematically by lines 1211, 1212, 1213, 1214, and 1215. The lines 1211 and 1215 are directed symmetrically and refer to the same lateral optical mode. The lines 1212 and 1214 are directed symmetrically and refer to the same, but a different lateral optical mode. The light in each mode impinges on a diffraction grating mounted on a dielectric holder 1230. The light 1211 through 1215 impinges on the diffraction grating 1231.through 1235, respectively. Each diffraction grating provides the feedback preferably only for a single wavelength within the gain spectrum of the gain chip 1210. Each pair of symmetrically positioned gratings preferably provides the feedback at the same wavelength. Thus, the gratings 1231 and 1235 provide the feedback at the wavelength λ₁, the gratings 1232 and 1234 provide the feedback at the wavelength λ₂, and the grating 1233 provide the feedback at the wavelength λ₃. The wavelength-selective at a few different wavelengths feedback results in wavelength-stabilized lasing at a few different wavelengths at the same time. Multi-wavelength laser light 1240 come out of the holder 1230. Optionally, a lens with a variable focal length 1220 can be used to form a parallel beam 1250, or a beam close to parallel, similar to the embodiment of FIG. 11C.

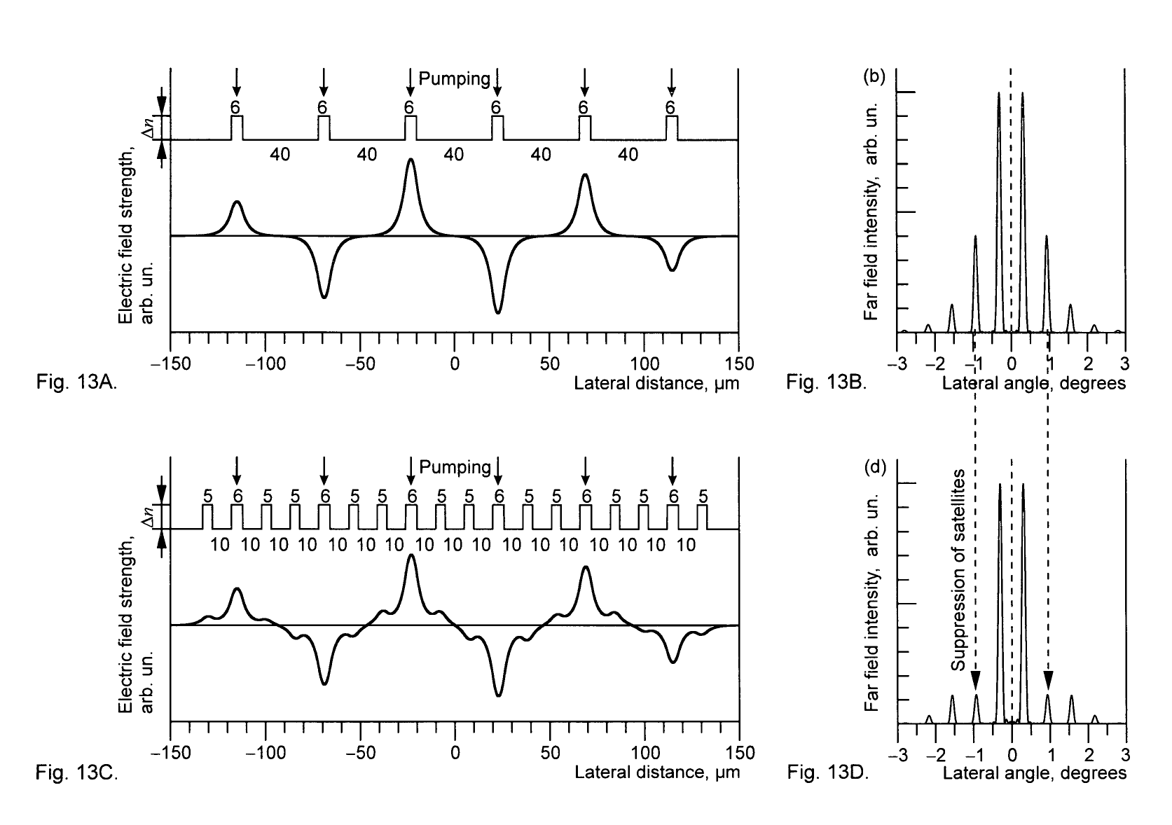

FIGS. 13A through 13D illustrate the principles of a built-in lens (or built-in-a-chip lens). FIG. 13A shows schematically a lateral profile of the effective refractive index for a multistripe chip. In particular, the chip in FIG. 13A has 6 stripes. For the particular embodiment, the stripes have the width 6 μm, the intervals 40 μm, the wavelength of light 1 μm. Also, the near field of the out-of-phase (or oscillating) lateral optical mode is shown. FIG. 13A represents not the intensity, but the electric field strength of the optical mode, wherein the electric field changes sign in each interval between the neighboring stripes. FIG. 13B shows the lateral far field profile of the optical mode of FIG. 13A. FIG. 13C refers to a multistripe chip with additional stripes. The lateral profile of the effective refractive index shows 2 additional stripes, 5 μm each between the original stripes. Preferably, only stripes identical with the stripes of FIG. 13A are pumped, and additional stripes are unpumped. A one skilled in the art will appreciate that additional stripes having effective refractive index larger than that in the intervals between the stripes enable efficient “resonant tunneling” of the lateral optical mode between the “original” (pumped 6-μ-m-wide) stripes. The lateral near field shown as the lateral spatial profile of the electric field strength in FIG. 13C confirms a larger absolute value of the electric field between the “original” stripes than that in FIG. 13A. Among a large plurality of the lateral optical modes, FIG. 13C shows the particular lateral optical mode having the maximum intensity in the pumped stripes. The comparison of FIGS. 13A and 13C shows that this mode originates from the mode of FIG. 13A, but has a larger intensity of the electric field between the pumped stripes due to efficient “resonant tunneling” mediated by additional stripes. FIG. 13D shows the lateral far field profile of the lateral optical mode of FIG. 13C. Due to stronger coupling between pumped stripes, the side satellites in the far field profile of FIG. 13D are suppressed as compared to FIG. 13B.

A one skilled in the art will agree that the embodiment of FIGS. 13A through 13D can be understood as a built-in lens (or a built-in-a-chip) lens. Such a lens has a similar functionality as a set of lenses of FIG. 3A as well as a lens with a variable focal length of FIG. 11C. Moreover, regarding to FIG. 13C two additional stripes placed between the original unpumped stripes form a diffracting element having the width of (5+10+5) twenty micrometers that exceeds the width of the original stripe 6 μm. This underlines a similarity between the lenses of FIG. 3A, on the one hand, and the built-in lenses of FIG. 13C, on the one hand, as in both embodiments additional diffracting elements have a size larger than the size of the original source of light.

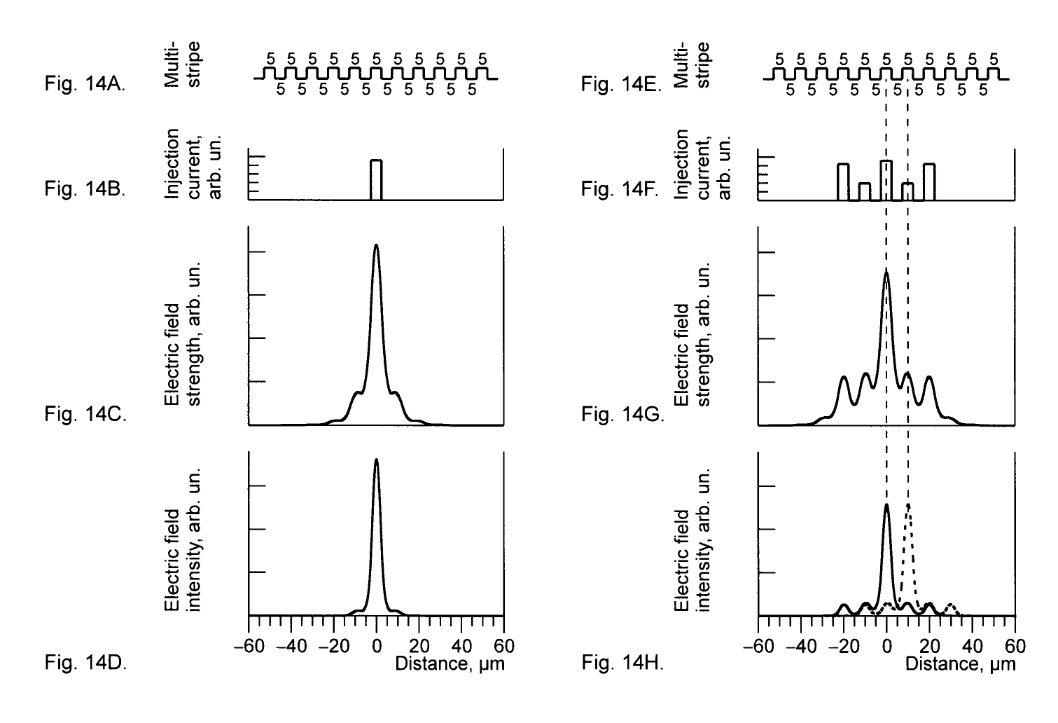

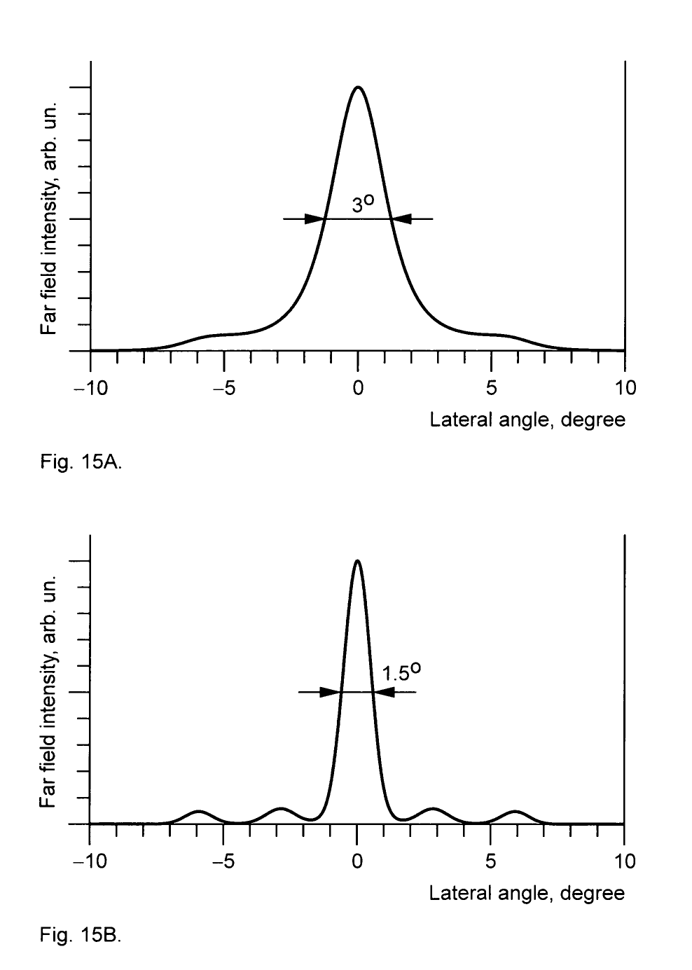

FIGS. 14A through 14H and 15A and 15B illustrate a built-in-a-chip lens according to another embodiment of the present invention. Arrays of lasers are frequently used for scanning and reading. The resolution of the device is determined by a distance between the neighboring chips. FIG. 14A shows schematically a multistripe array of lasers, wherein each stripe is 5 μm wide, and the spacing between the stripes is also 5 μm. The device is operated by injection current applied separately to each stripe. FIG. 14B shows an example of the injection current applied to a single stripe. Injection current induced a refractive index change in the pumped stripe with respect to the unpumped stripes. The near field distribution (FIG. 14C) is modeled under an assumption of the step in the effective refractive indices between the stripe and the spacing equal Δn_{eff}=0.001, and the current-induced change Δn_{eff}^{current}=0.00023. FIG. 14C displays the electric field strength profile, and FIG. 14D displays the intensity profile. FIG. 15A shows the far field profile revealing a peak with 3 degrees full width at half maximum (FWHM).

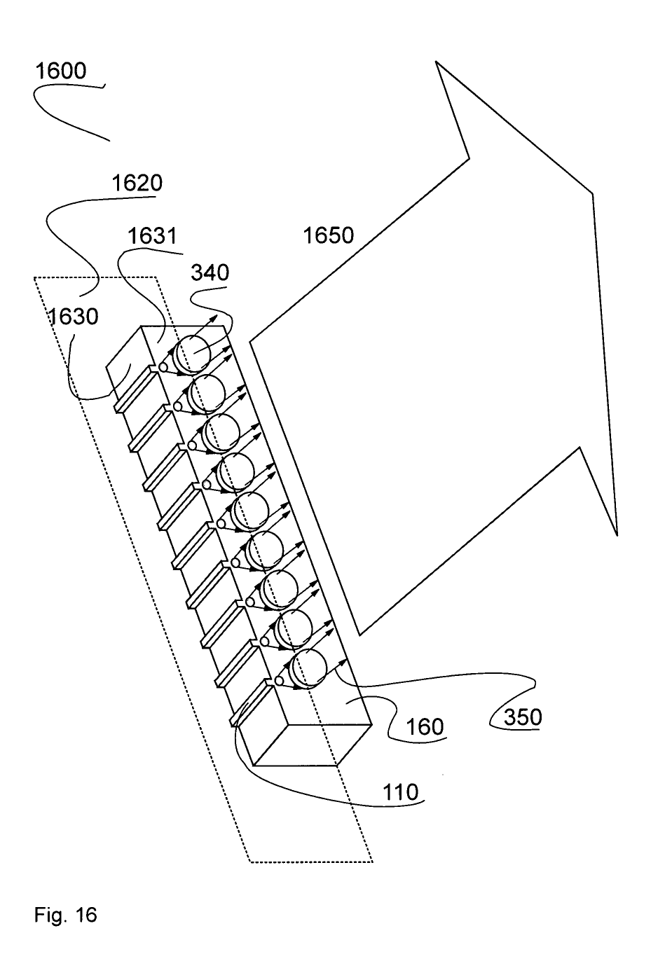

Due to divergence of the laser beam, the scanning or reading is typically being performed in the vicinity to the object to scan. However, there is a need to scan objects located at a certain distance from the device, e. g. if the objects are located in a non-friendly environment, say at a ho or wet place ro in the presence of, chemical agents. A possibility to operate a scanning device at a distance is limited by the divergence of the beam. A possible reduction of the beam divergence by increasing a size of a single chip/separation between neighboring chips does not really give an improvement, since a smaller number of the devices per unit length will then reduce the resolution. FIGS. 14E through 14H and 15B demonstrate a possibility to improve the beam divergence without reducing the resolution. FIG. 14E shows schematically a multistripe array of lasers, similar as that of FIG. 14A. FIG. 14F explains a way of device operation. A signal applied to every single stripe is applied as injection current applied with predefined amplitudes to a group of neighboring stripes. For a particular modeling the current-induced change of the effective refractive index in assumed to occur in five stripes and be equal to 0.00021, 0.00010, 0.00023, 0.00010, and 0.00021. Since the vertical waveguide is a broad waveguide, the optical fields are coupled, and the lateral optical mode emited from this group of five stripes is shown in FIG. 14G. Besides the central peak, some pedestal evolves. Whereas this pedestal has a moderate relative value in the profile of the electric field strength in FIG. 14G, it is rather small in the intensity profile of FIG. 14H, wherein the intensity profile is shown by a solid line. The only effect of this pedestal is a small reduction in the intensity of the central maximum in FIG. 14H with respect to that of FIG. 14D. At the same time, the far field profile shown in FIG. 15B has a twice smaller full width at half maximum as the conventional profile of FIG. 15A. One should bear in mind, that, despite the fact, that addressing a single stripe implies a predefined injection of the current in a few (five) neighboring stripes, already the nearest stripe can be addressed independently by injection a current into a group of five stripes shifted by one. Once in the first time moment the injection current profile is the one represented in FIG. 14F, after a time step a similar injection current profile will be shifted by one stripe. The intensity profile of the optical field will then be the one shown by a short dashed line in FIG. 14H. Two dashed lines extended from FIG. 14H to FIG. 14E show that the well pronounced maxima of the two intensity profiles occur at two neighboring stripes. Thus, the built-in-lens as presented in FIGS. 14A through 15B indeed allows reduction of the beam divergence without loss in resolution. FIG. 16 shows schematically an optoelectronic system 1600, wherein an additional means is introduced to stabilize the single lateral mode operation. The chip 1630 is preferably similar to that of the embodiment of FIG. 3A. In addition, the front facet 1631 is preferably covered by an anti-reflecting coating. The reflectivity of the front facet covered by the anti-reflecting coating is preferably between 0.01 and 0.03. The differential efficiency defined for the light emission through the front facet is preferably above 80%. The rear facet can be also covered by a coating, providing a moderately high reflectivity. The reflectivity of the rear facet is preferably between 0.3 and 0.5.

An additional external mirror 1620 is attached to the rear facet. This mirror provides an additional reflectivity for the fundamental lateral mode and stabilizes it. Thus, such an embodiment further stabilizes a single lateral mode operation of the optoelectronic system. Light 1150 coming out of the system is then a single mode light.

In yet another embodiment of the present invention, the back external mirror is a wavelength-selective mirror.

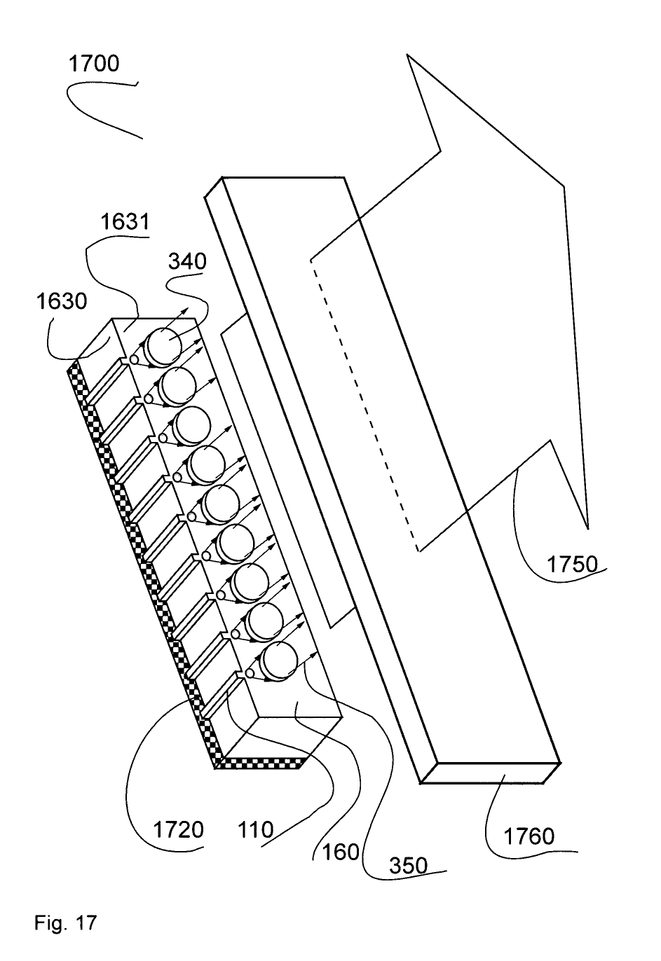

FIG. 17 shows schematically an optoelectronic system 1700 according to a further embodiment of the present invention. A high-reflection coating 1720 is mounted on the rear facet of the chip 1630. A holographic Bragg grating 1760 is positioned in front of the front facet 1631 of the chip 1630. The holographic Bragg grating provides a wavelength-selective operation of the system 1700, which then emits wavelength-stabilized light 1750.

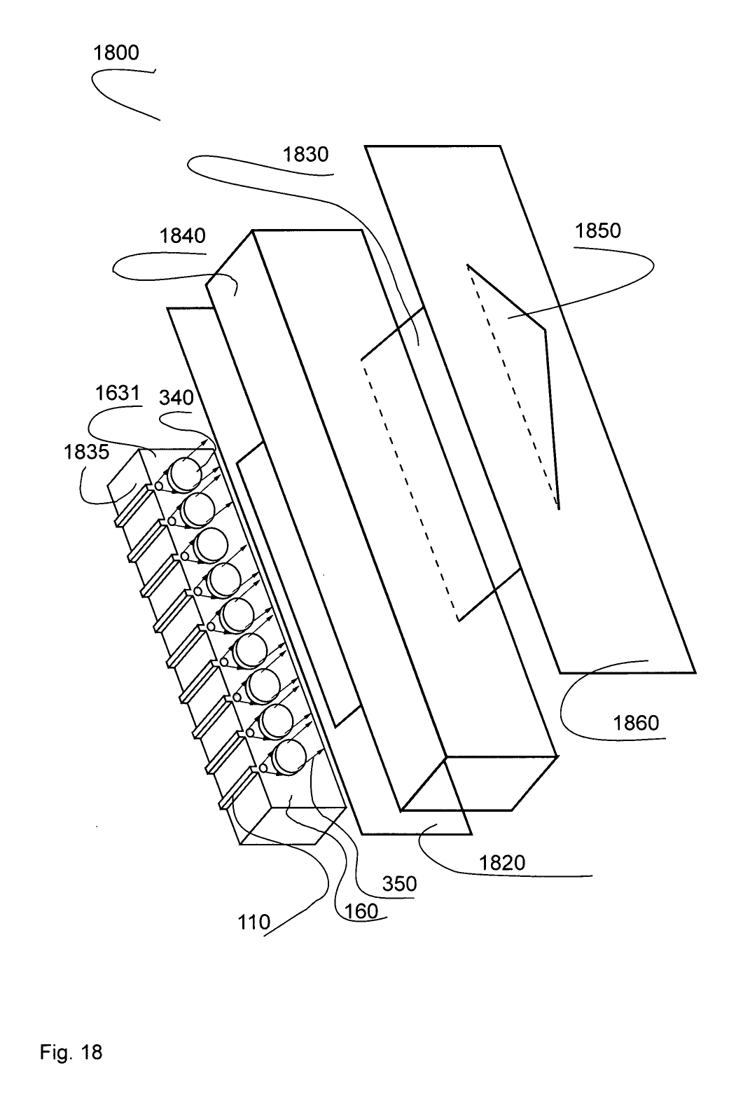

FIG. 18 shows schematically a system 1800 for frequency conversion, according to another embodiment of the present invention. A source of coherent laser light 1835 combined with an array of lenses 340 to improve the beam quality emits primary light in a form of a coherent laser beam that propagates within an external cavity. A non-linear crystal 1840 is placed in the external cavity. The non-linear crystal is preferably surrounded by two external mirrors. A first mirror 1820 is placed between the source of the primary light 1835 and the non-linear crystal 1840. The first mirror is semi-transparent for the primary light and is reflecting for the frequency-converted light. The second mirror 1860 is placed adjacent to the non-linear crystal on the side opposite to the first mirror. The second mirror is preferably reflecting to the primary light and semi-transparent to the frequency-converted light. The non-linear crystal is preferably capable to generate the second harmonic of the primary light. The light at the second harmonic 1850 having an improved beam quality comes out of the system through the second semi-transparent mirror 1860.

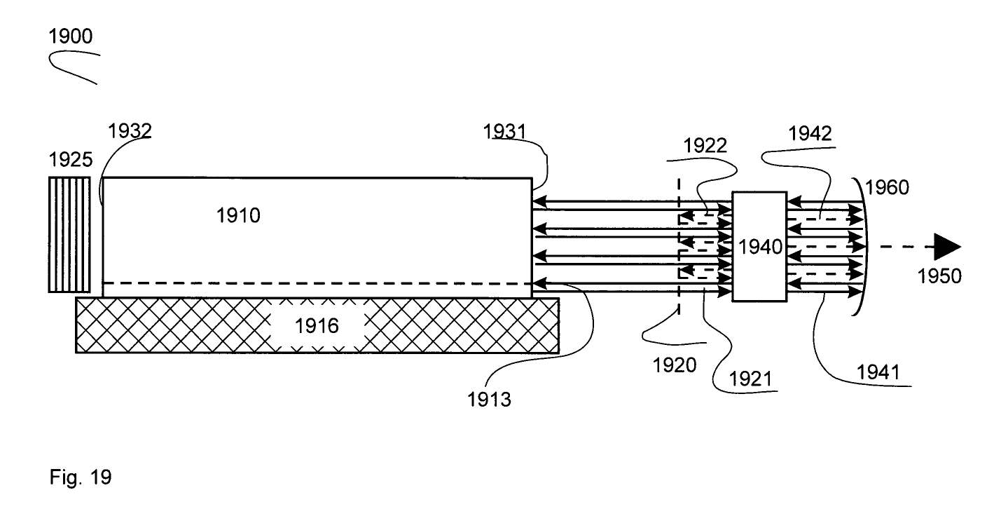

FIG. 19 shows schematically a system 1900 for frequency conversion, according to yet another embodiment of the present invention. A chip 1910 generating light at a first harmonic has preferably a thick vertical waveguide, and the gain region 1913 is positioned close to the heat sink 1916. A highly reflecting mirror 1925 preferably formed as a dielectric distributed Bragg reflector or a holographic grating is placed behind the rear facet 1932. In front of the front facet 1931, a first mirror 1920, a non-linear crystal 1940, and a second mirror 1960 are positioned. The non-linear crystal 1940 generates the second harmonic of the light. Between the first mirror 1920 and the non-linear crystal 1940, both light of the first harmonic 1921 and light of the second harmonic 1922 are present. Between the non-linear crystal 1940 and the second mirror 1960 both light of the first harmonic 1941 and light of the second harmonic 1942 are present. The first mirror is preferably semi-transparent for the first harmonic and not transparent for the second harmonic to preferably exclude the light of second harmonic impinging on the chip generating primary light. The second mirror 1960 is preferably semi-transparent for the second harmonic and not—transparent for the first harmonic to hinder the radiation of the first harmonic which is not in use and just mean losses. The light of the second harmonic 1950 comes out through the second mirror.

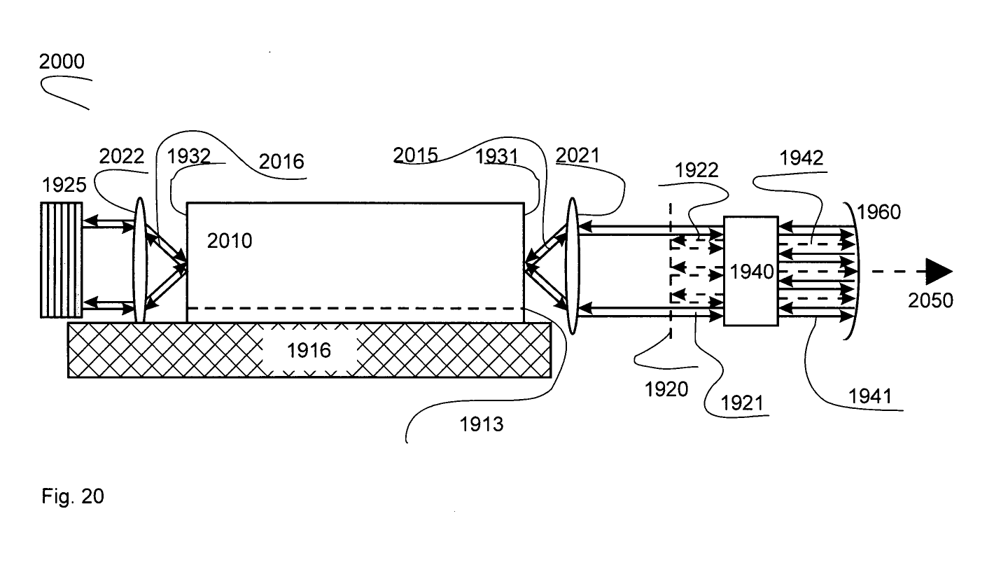

FIG. 20 shows schematically a system 2000 for frequency conversion, according to a further embodiment of the present invention. The gain chip 2010 is a semiconductor gain chip having a thick vertical waveguide and is configured as a passive cavity edge-emitting gain chip.

Most of the optical power is emitted in a form of two narrow vertical lobes. The light 2015 emitted in the form of two narrow vertical lobes from the front facet 1931 impinges on a lens 2021 and is transformed into a nearly parallel beam. It is preferred that the beams formed by the lens 2021 are directed parallel to the lateral plane or at an angle which does not exceeds 0.5 degrees with respect to the lateral plane and have the full width at half maximum which does not exceed 0.5 degrees. This nearly parallel beam impinges on a non-linear crystal 1940. The light 2016 emitted in the form of two narrow vertical lobes from the rear facet 1932 impinges on a lens 2022 and is transformed into a nearly parallel beam impinging on a highly reflecting mirror 1925. Using a semiconductor gain chip with a thick vertical waveguide for frequency conversion has a significant advantage since a large output facet facilitates back coupling of light to the gain chip. Once the light generated by the gain chip is emitted in a form of two narrow vertical lobes, using a lens will transform it to a nearly parallel beam for further application for the generation of the second harmonic light which comes out of the system 2050 through the mirror 1960.

In another embodiment of the present invention, a tilted wave semiconductor gain chip is used as a source of primary light for a system for frequency conversion.

A one skilled in the art will appreciate that the systems for frequency conversion disclosed in the embodiments of FIGS. 18, 19 and 20 are well suited to generate green light with the wavelength close to 530 nm out of primary light with the wavelength close to 1060 nm, wherein a diode gain chip can be well used for generating primary light.

Further to all above described embodiments of the present invention, the set of the lenses can be arranged, if necessary in both directions thus improving the beam quality also in both directions.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

Although the invention has been illustrated and described with respect to exemplary embodiments thereof, it should be understood by those skilled in the art that the foregoing and various other changes, omissions and additions may be made therein and thereto, without departing from the spirit and scope of the present invention. Therefore, the present invention should not be understood as limited to the specific embodiments set out above but to include all possible embodiments which can be embodied within a scope encompassed and equivalents thereof with respect to the feature set out in the appended claims.

What is claimed is:

1. An optical system comprising at least two primary sources of light coherent to each other,
wherein each primary source of light has an output aperture;
wherein apertures of said at least two primary sources of light are separated by a distance exceeding the size of the apertures;
wherein the far field pattern of the coherent emitters represents a multilobe pattern wherein diffracting elements are introduced;
wherein the size of the diffracting elements exceeds the size of the apertures;
wherein the full width at half maximum of the multilobe far field pattern of the emitted light diffracted at the diffracting elements is reduced with respect to the full width at half maximum of the multilobe far field pattern of the coherently coupled sources of light by at least fifty per cent.

2. The optical system of claim 1, wherein at least one source of light of said at least two primary sources of light is a semiconductor diode chip selected from the group consisting of:
a) semiconductor laser diode;
b) semiconductor light-emitting diode;
c) semiconductor gain chip.

3. The optical system of claim 1, wherein said diffracting elements are selected from the group consisting of:
a) collimating lens;
b) collimating minor; and
c) built-in-a-chip lens.

4. The optical system of claim 3, wherein said diffracting elements are positioned at a distance from the apertures, the distance not exceeding twice the focal length of said diffracting element.

5. The optical system of claim 3, wherein said diffracting elements are positioned at one plane.

6. The optical system of claim 3, wherein said diffracting elements are positioned at different planes.

7. The optical system of claim 3, wherein the size of said diffracting elements exceeds seventy per cent of the distance between the primary sources of light.

8. The optical system of claim 1, further comprising
an element configured to turn the optical beam.

9. The optical system of claim 1,
wherein said at least two primary sources of light coherent to each other are selected from the group consisting of:
a) at least two stripes on top of a single semiconductor diode laser chip coherently coupled by evanescent coupling;
b) at least two illuminated spots on an external minor in a system of semiconductor diode gain sections or chips coherently coupled in an external resonator.

10. The optical system of claim 9,
wherein said single semiconductor diode laser gain section or chip is selected from the group consisting of:
a) a passive cavity laser;
b) a tilted wave laser;
c) a laser based on a vertical photonic band crystal;
d) a slab-coupled ridge laser diode;
e) a laser based on a large optical cavity vertical waveguide.

11. An optical system for frequency conversion, comprising at least one semiconductor diode gain chip further comprising a coherently coupled array of stripes as a source of primary light.

12. The optical system of claim 11,
wherein said at least one semiconductor gain chip is a set of semiconductor diode gain chips selected from the group consisting of:
a) a bar of gain sections or chips coherently coupled in an external resonator; or
b) a stack of gain sections or chips coherently coupled in an external resonator; or
c) a stack of gain sections or chips coherently coupled by amplification of the same laser mode from distributed through the said gain sections or chips; or
d) a combination of a) through c).

13. The optical system of claim 9,
wherein the coherent laser sources are wavelength stabilized by the effect selected from the group consisting of:
a) distributed feedback effect within the laser stripes,
b) wavelength-selective mirror;
c) wavelength selective loss element; and
d) diffraction grating.

14. The optical system of claim 11, further comprising
a nonlinear crystal for frequency conversion and
a mirror to reflect the primary light back to the system while transmit the frequency-converted light.

15. The optical system of claim 11,
wherein said at least one semiconductor gain chip further comprises a thick vertical waveguide,
wherein said thick vertical waveguide has a thickness exceeding three times the wavelength of the emitted light in the vacuum.

16. The optical system of claim 15,
wherein said at least one semiconductor gain chip emits light in the form of two narrow vertical lobes,
wherein said narrow vertical lobe is a lobe with a full width at half maximum below five degrees.

17. The optical system of claim 16, further comprising at least one collimating lens,
wherein said at least one collimating lens transforms said two narrow vertical lobes into two nearly parallel beams,
wherein said nearly parallel beam is a beam directed at an angle less than zero point five degrees with respect to the lateral plane and having a full width at half maximum less than zero point five degrees.

18. The optical system of claim 9, wherein the optical power of the elements can be tuned independently resulting in the beam steering of the resulting beam.

19. The optical system of claim 9 capable to generate high power optical pulses due to the effect selected from the group consisting of:
a) a mode-locking, and
b) Q-switching.
